(19) United States
(12) Patent Application Publication
(10) Pub. No.: US 2007/0263355 A1
(43) Pub. Date: Nov. 15, 2007

(54) HEAT DISSIPATION SYSTEM

(75) Inventors: Guang Yu, Shenzhen (CN); Da-Yuan Zhou, Shenzhen (CN); Shih-Hsun Wung, Tu-Cheng (TW); Chun-Chi Chen, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., Tu-Cheng (TW)

(21) Appl. No.: 11/309,837

(22) Filed: Oct. 9, 2006

(30) Foreign Application Priority Data
May 12, 2006 (CN) 200610060623.3

(51) Int. Cl. H05K 7/20

(52) U.S. Cl. 361/700

(57) ABSTRACT

A heat dissipation system is used for dissipating heat generated by an electronic device. The heat dissipation system includes a computer enclosure containing the electronic device therein. The computer enclosure has a heat dissipating member formed thereon. A base contacts the electronic device in the computer enclosure. At least a heat pipe includes a first end thermally engaged in at least a groove defined in the base and a second end thermally contacting the computer enclosure. A heat sink is mounted on the base and thermally connects with the base and the first end of the at least a heat pipe.

### FIELD OF THE INVENTION

The present invention relates to heat dissipation devices for use in removing heat from electronic devices, and more particularly to a heat dissipation device incorporating heat pipes and an enclosure of an electronic equipment for improving heat dissipation efficiency of the heat dissipation device.

### DESCRIPTION OF RELATED ART

During operation of an electronic device such as a central processing unit (CPU), a large amount of heat is often produced. The heat must be quickly removed from the electronic device to prevent it from becoming unstable or being damaged. Typically, a heat sink is attached to an outer surface of the electronic device to absorb the heat from the electronic device. The heat absorbed by the heat sink is then dissipated to ambient air.

Typically, the heat sink comprises a solid metal base attached on the electronic device, and a plurality of fins arranged on the base. The base is intimately attached to the electronic device thereby absorbing the heat generated by the electronic device. Most of the heat accumulated at the base is transferred to the fins and then dissipates away from the fins. Generally, the heat sink is constructed to meet heat dissipation demand of the heat generating electronic device by increasing the area and amount of the fins thereof. However, the speedy upgrading trend in computer industry causes the electronic device to become more and more powerful, which results in that more and more heat is produced in the computer. Furthermore, a height of the computer is required to be smaller and smaller. Consequently, the aforesaid heat sink can no longer meet the heat dissipation requirement of the electronic device.

What is needed, therefore, is a heat dissipation system which can achieve a greater heat dissipation capability.

### SUMMARY OF THE INVENTION

A heat dissipation system in accordance with a preferred embodiment of the present invention is used for dissipating heat generated by electronic devices. The heat dissipation system comprises a computer enclosure containing an electronic device therein. The computer enclosure has a heat dissipating member thermally formed thereon. A base contacts the electronic device in the computer enclosure. At least a heat pipe comprises a first end thermally engaged in at least a groove defined in the base and a second end thermally contacting the computer enclosure. A heat sink is mounted on the base and thermally connects with the first end of the at least a heat pipe. Heat generated by the electronic device has a portion dissipated to ambient air in the computer through the heat sink, and another portion dissipated to ambient air outside the computer through the at least a heat pipe and the computer enclosure.

Other advantages and novel features of the present invention will become more apparent from the following detailed description when taken in conjunction with the accompanying drawings, in which:

### BRIEF DESCRIPTION OF THE DRAWINGS

Many aspects of the present apparatus can be better understood with reference to the following drawings. The components in the drawings are not necessarily drawn to scale, the emphasis instead being placed upon clearly illustrating the principles of the present apparatus. Moreover, in the drawings, like reference numerals designate corresponding parts throughout the several views.

FIG. 1 is an exploded, isometric view of a heat dissipation system in accordance with a preferred embodiment of the present invention;

FIG. 2 is an assembled view of FIG. 1; and

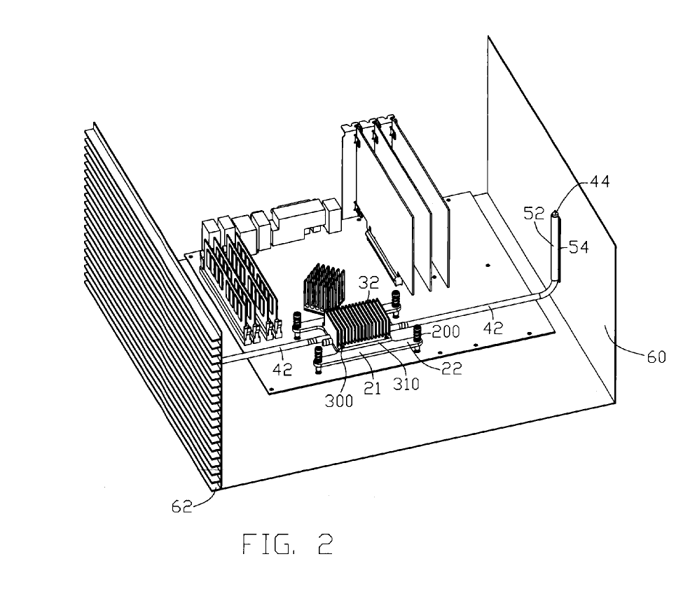

FIG. 3 is an assembled view of FIG. 1, but viewed from another aspect.

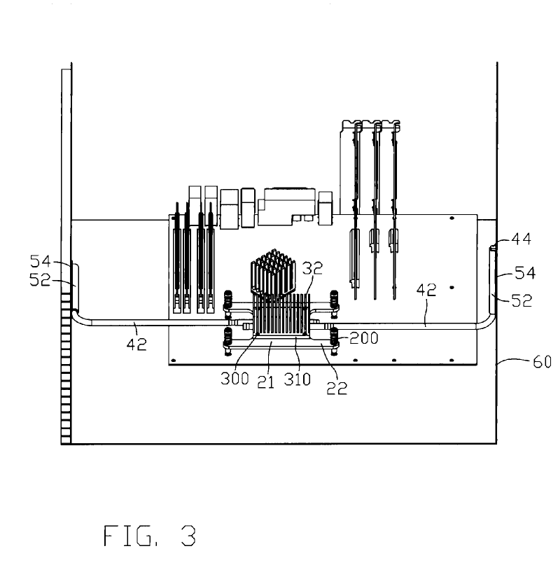

### DETAILED DESCRIPTION OF THE INVENTION

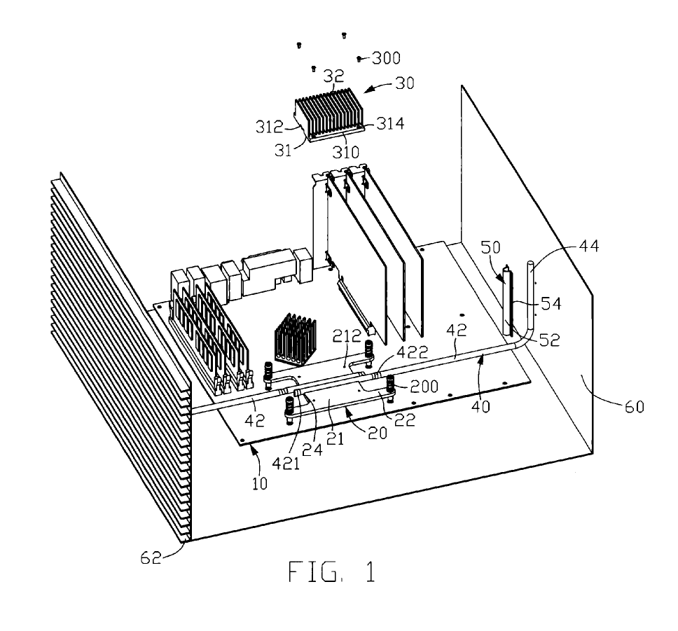

Referring to FIG. 1, a heat dissipation system in accordance with a preferred embodiment of the present invention is shown. The heat dissipation system is used for dissipating heat generated by an electronic device such as a CPU (not shown) located on a printed circuit board 10 in a computer enclosure 60. The heat dissipation system comprises a base 20, a heat sink 30 located on the base 20, two heat pipes 40 sandwiched between the base 20 and the heat sink 30 and the computer enclosure 60.

The base 20 is made from good heat conducting metal such as copper, aluminum and so on, and comprises a substantially rectangular main body 21 and four arms 22 extending from four corners of the main body 21. The main body 21 has a bottom face contacting the CPU. Two parallel grooves 24 are transversely defined in a top face of the main body 21. Each of the two grooves 24 has a semicircular cross section. In the case, the two grooves 24 are located close to each other and span across the top face of the main body 21. The main body 21 defines four through apertures 212 at corresponding four corners thereof. The four arms 22 of the base 20 are parallel to each other, and each defines a fixing hole (not labeled) accommodating a fastener 200 adjacent to a distal end of the corresponding arm 22.

The heat sink 30 is made from good heat conducting metal such as copper, aluminum and so on, and comprises a base plate 31 and a plurality of fins 32 substantially perpendicularly extending from a top face of the base plate 31. In this case, the heat sink 30 is formed by extruding a metal block. The base plate 31 has a bottom face thermally contacting the top face of the base 20 and defining two grooves 312 corresponding to the grooves 24 of the base 20. The two grooves 312 are extended perpendicular to the fins 32 and each has a semicircular cross section. The fins 32 are spaced a certain distance from each other and parallel to each other on the base plate 31. The base plate 31 has a pair of shoulders 310 at two opposite sides thereof, respectively, extending outwardly beyond the fins 32. Each shoulder 310 defines two fixing holes 314 corresponding to the through apertures 212 of the base 20. Four bolts 300 are brought to extend through corresponding fixing holes 314 of the shoulder 310 and screw in the through apertures 212 of the base 20 to fix the heat sink 30 to the base 20.

Each heat pipe 40 is substantially L-shaped in profile, and comprises a first end 42 received in corresponding groove 24 of the base 20 and groove 312 of the base plate 31, and a second end 44 attached to the computer enclosure 60. The second ends 44 of the two heat pipes 40 are located at two sides of the heat sink 30 and are attached to two opposite faces of the computer enclosure 60 by two connecting members 50. Each connecting member 50 is integrally made from heat conducting metals such as copper, aluminum and so on, and comprises a camber portion 52 and two fixing flanges 54 extending from two opposite sides of the camber portion 52, respectively. The second end 44 of the heat pipe 40 is sandwiched between the camber portion 52 and the face of the computer enclosure 60. The fixing flanges 54 are fixed to the computer enclosure 60 by welding or screws. Thermally grease is filled in the grooves 24, 312 between the first ends 42 of the heat pipes 40, the base 20 and the base plate 31 of the heat sink 30, to reduce heat resistance therebetween. Thermally grease is filled between the second ends 44 of the heat pipes 40, the enclosure 60 and the connecting member 50 to reduce heat resistance therebetween. In this case, the enclosure 60 has a plurality of fins 62 extending from an outer face thereof, which increases heat dissipation area of the enclosure 60.

In use, the base 20 absorbs heat generating the CPU. The heat in the base 20 partly is transferred to the heat sink 30 and partly is absorbed by the first ends 42 of the heat pipes 40 and is transferred to the enclosure 60 via the second ends 44 of the heat pipes 40. Therefore, the heat generated by the CPU is dissipated away by the heat sink 30 and the enclosure 60. Each of the first ends 42 of the heat pipes 40 forms a first bulge 421 at a free edge thereof and a second bulge 422 between the free edge and the second end 44. In this case, the first and second bulges 421, 422 are located beside two sides of the groove 24 and space distances therefrom, respectively. The distances are used for allowing adjustment of horizontal position of the heat pipe 40 to compensate a tolerance of a width between two sidewalls (not labeled) of the computer enclosure 60. The bulges 421, 422 function as blocks to limit the horizontal movement of the heat pipe 40.

According to the preferred embodiment of the present invention, the heat pipes 40 connect the base 20 and the enclosure 60 to transfer the heat in the base 20 to the enclosure 60. Therefore, the enclosure 60 is utilized to dissipate the heat generated by the CPU, which increases heat dissipating area of the heat dissipation system; accordingly, heat dissipation capacity of the heat dissipation system is improved.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation system used for dissipating heat generated by an electronic device in an enclosure of an electronic equipment, the heat dissipation system comprising:
a base adapted for contacting the electronic device for absorbing heat generated by the electronic device, the base defining a groove therein; and
a heat pipe having a first end received in the groove of the base and a second end adapted for thermally contacting the enclosure for transferring the heat from the base to the enclosure.

2. The heat dissipation system of claim 1 further comprising a heat sink located on the base and thermally connecting with the base and the first end of the heat pipe.

3. The heat dissipation system of claim 2, wherein the heat sink defines a groove receiving the first end of the heat pipe therein, and wherein the heat pipe is substantially L-shaped.

4. The heat dissipation system of claim 3, wherein the heat sink comprises a base plate thermally contacting the base and a plurality of fins extending from the base plate.

5. The heat dissipation system of claim 4, wherein the groove of the heat sink is defined in a bottom face of the base plate corresponding to the groove of the base.

6. The heat dissipation system of claim 1, wherein the second end of the heat pipe is attached to the enclosure by a connecting member.

7. The heat dissipation system of claim 6, wherein the connecting member comprises a camber portion and two flanges extending from two sides of the camber portion, respectively, and fixed to the enclosure, the second end of the heat pipe being sandwiched between the camber portion and the enclosure.

8. The heat dissipation system of claim 1 further comprising a second heat pipe, wherein the second heat pipe comprises a first end thermally contacting the base, and a second end thermally connecting with the enclosure.

9. The heat dissipation system of claim 8, wherein the second ends of the two heat pipes are located at two opposite sides of the base.

10. The heat dissipation system of claim 1, wherein the enclosure extends a plurality of fins outwardly.

11. The heat dissipation system of claim 1, wherein the base extends a plurality of fixing arms for fixing the base to a printed circuit board via a plurality of fasteners.

12. The heat dissipation system of claim 1, wherein the first end of the heat pipe forms two spaced bulges located beside two sides of the groove, respectively, the bulges functioning as blocks to limit horizontal movement of the heat pipe.

13. A heat dissipation system used for dissipating heat generated by an electronic device, the heat dissipation system comprising:
an enclosure adapted to receive the electronic device therein, the enclosure having a heat dissipating member formed thereon;
a base adapted for contacting the electronic device in the enclosure; and
at least a heat pipe comprising a first end thermally contacting the base and a second end thermally contacting the enclosure.

14. The heat dissipation system of claim 13, wherein the heat dissipating member comprises a plurality of fins extending from the enclosure.

15. The heat dissipation system of claim 13 further comprising a heat sink located on the base.

16. The heat dissipation system of claim 15, wherein the heat sink comprises a base plate thermally contacting the base and a plurality of fins extending from the base plate.

17. The heat dissipation system of claim 16, wherein the first end of the at least a heat pipe thermally contacting the base plate of the heat sink.

18. The heat dissipation system of claim 13, wherein the second end of the at least a heat pipe is attached to the enclosure by a connecting member comprising a camber portion and two flanges extending from the camber portion, the second end being located between the camber portion and the enclosure, the flanges being fixed to the computer enclosure.

19. The heat dissipation system of claim 13, wherein the first end of the at least a heat pipe forms two spaced bulges thereon, the bulges being located beside two sides of the base, respectively, for limiting horizontal movement of the at least a heat pipe.
